(19) United States
(12) Patent Application Publication
(10) Pub. No.: US 2025/0230573 A1
(43) Pub. Date: Jul. 17, 2025

(54) COLLOIDAL CRYSTAL AND PRODUCTION METHOD THEREFOR

(71) Applicants: Public University Corporation Nagoya City University, Nagoya-shi, Aichi (JP); MURATA MANUFACTURING CO., LTD., Nagaokakyo-shi, Kyoto (JP)

(72) Inventors: Junpei YAMANAKA, Nagoya-shi (JP); Akiko TOYOTAMA, Nagoya-shi (JP); Tohru OKUZONO, Nagoya-shi (JP); Yurina AOYAMA, Nagoya-shi (JP); Ami MATSUO, Nagoya-shi (JP); Tatsuya ISHIKAWA, Nagaokakyo-shi (JP); Koichiro HYODO, Nagaokakyo-shi (JP); Masaya NISHIDA, Nagaokakyo-shi (JP)

(73) Assignees: Public University Corporation Nagoya City University, Nagoya-shi, Aichi (JP); MURATA MANUFACTURING CO., LTD., Nagaokakyo-shi, Kyoto (JP)

(21) Appl. No.: 18/702,872

(22) PCT Filed: Oct. 18, 2022
(86) PCT No.: PCT/JP2022/038829

§ 371 Date: Apr. 19, 2024

(30) Foreign Application Priority Data
Oct. 20, 2021 (JP) 2021-171446

(51) Int. Cl. C30B 5/00; C30B 29/16; C30B 29/66

(52) U.S. Cl. CPC C30B 5/00; C30B 29/16; C30B 29/66

(57) ABSTRACT

There are provided a colloidal crystal having a four-fold symmetric pattern and capable of stably existing even in a geometrically unconstrained space, and a method for producing the same.

The colloidal crystal of the present invention exists in a geometrically unconstrained space and has a four-fold symmetric pattern. The colloidal crystal of the present invention can be produced by filling a dispersion of colloidal particles between a substrate 1 and an opposed plate 2 facing the substrate 1 to precipitate a charged colloidal crystal having a four-fold symmetric pattern (crystallization step S1); and electrostatically adsorbing and immobilizing, onto the substrate 1, the charged colloidal crystal having a four-fold symmetric pattern (immobilization step S2).

### TECHNICAL FIELD

The present invention relates to a colloidal crystal having a four-fold symmetric pattern and a method for producing the same.

### BACKGROUND ART

The colloid is a state in which a dispersion phase is dispersed in a dispersion medium, and when the dispersion medium is liquid, the colloid is referred to as colloidal dispersion. The “charged colloidal particles” having a charge on their surface align regularly and spontaneously with a distance between particles in a colloidal dispersion when appropriate conditions are selected, due to electrostatic repulsive force acting between the particles. This structure is called a charged colloidal crystal. The charged colloidal crystal is known to have either a body-centered cubic lattice (BCC) type structure or a face-centered cubic lattice (FCC) structure depending on conditions (Non-Patent Literature 1).

A charged colloidal crystal from a colloidal dispersion is formed in a self-organized manner as its colloidal particles attempt to have a thermodynamically stable structure. Therefore, there is an advantage that no precise processing technique is necessary, unlike in the case of a lithographic method or the like. In addition, it can be used as a photonic material corresponding to various wavelengths by selecting a diameter of the colloidal particles. Therefore, many studies have been made on the production of colloidal crystals.

Usually, a (111) plane of a face-centered cubic lattice (FCC) having six-fold symmetry is oriented in a container wall or substrate. A method using a constrained space has been developed as a technique for allowing a plane oriented in a substrate to have four-fold symmetry (Non-Patent Literature 2). In this method, a phenomenon that a six-fold symmetric pattern or a four-fold symmetric pattern is formed by adjusting a ratio of a particle diameter to a length of a gap in a constrained space (that is, a geometrically restricted space) having a gap of about 1 to 100 μm is used (see FIG. 20).

However, a method for producing a colloidal crystal having a four-fold symmetric pattern using such a constrained space involves a problem that the colloidal crystal having a four-fold symmetric pattern cannot be maintained unless a special environment such as a constrained space having a gap of about 1 to 100 μm is maintained, which is an obstacle in a case where the colloidal crystal is used in a photonic material or the like.

### CITATIONS LIST

### Non-Patent Literature

Non-Patent Literature 1: “Colloidal Crystal, Formation, and Application thereof”, Supervised by Hiroshi Nakamura and Junpei Yamanaka, CMC Publishing Co., Ltd., 2020
Non-Patent Literature 2: Pieranski, P.; Strzelecki, L.; Pansu, B. Thin Colloidal Crystals. Phys. Rev. Lett. 1983, 50 (12), 900-903.

### SUMMARY OF INVENTION

### Technical Problems

The present invention has been made in view of the above conventional circumstances, and a problem to be solved is to provide a colloidal crystal having a four-fold symmetric pattern and capable of stably existing even in a geometrically unconstrained space, and a method for producing the same.

### Solutions to Problems

The colloidal crystal of the present invention exists in a geometrically unconstrained space and has a four-fold symmetric pattern. It is known that a four-fold symmetric pattern is generated in a geometrically constrained closed space (for example, a constrained space between two opposing planes) in a dispersion of colloidal particles as described above, but the colloidal crystal of the present invention can stably have a four-fold symmetric pattern even in an unconstrained space, not in such a geometrically constrained closed space. Therefore, when the colloidal crystal is used in an optical element or the like, it is not necessary to cause the colloidal crystal to exist in a geometrically constrained closed space, and the colloidal crystal provides an advantage of easy use.

The colloidal crystal of the present invention can be a two-dimensional colloidal crystal formed of a single layer or a three-dimensional colloidal crystal formed of a plurality of layers. Further, in the three-dimensional colloidal crystal, a first layer formed of first colloidal particles and a second layer formed of second colloidal particles are alternately repeated to form a multilayer structure, and a colloidal crystal in which a refractive index of the first colloidal particles or a refractive index of the second colloidal particles is the same as a refractive index of the dispersion medium can also be used. This can provide an effect that light passing through the colloidal crystal is not refracted by the second colloidal particles constituting the second layer, and that the second layer is transparent to light. That is, if a BCC crystal is stacked on a substrate with a (100) plane serving as the first layer and the second layer is made optically transparent, the particles of the first layer and the third layer that are not transparent form a simple cubic lattice (SC). This provides a special effect that it is possible to form optically the same structure as the structure of colloidal particles formed of a simple cubic lattice (SC) that cannot be formed only by self-assembly.

The colloidal crystal of the present invention can be produced as follows.

Namely, the colloidal crystal can be produced by a method for producing a colloidal crystal, the method including: a crystallization step of filling a dispersion of first colloidal particles between a substrate and an opposed plate facing the substrate to precipitate a charged colloidal crystal with a four-fold symmetric pattern formed of the first colloidal particles; and an immobilization step of electrostatically adsorbing and immobilizing, onto the substrate, the charged colloidal crystal with the four-fold symmetric pattern formed of a single layer of the first colloidal particles.

In the method for producing a colloidal crystal of the present invention, as a second layer formation step, a dispersion of second colloidal particles having a charge opposite to that of the first colloidal particles is brought into contact with the single layer of the first colloidal particles to electrostatically adsorb the second colloidal particles onto the single layer of the first colloidal particles after the immobilization step is performed, whereby a charged colloidal crystal having a four-fold symmetric pattern in which two layers are stacked can be obtained.

Further, as a third layer formation step, a dispersion of third colloidal particles having a charge opposite to that of the second colloidal particles is brought into contact with a single layer of the second colloidal particles to electrostatically adsorb the third colloidal particles onto the single layer of the second colloidal particles after the second layer formation step is performed, whereby a charged colloidal crystal having a four-fold symmetric pattern in which three layers are stacked can be obtained.

Further, the second layer formation step and the third layer formation step are alternately repeated, whereby a charged colloidal crystal having a four-fold symmetric pattern in which a plurality of layers of four or more layers are stacked can be obtained.

Also, a surface of the substrate or surfaces of the colloidal particles in the dispersions of the colloidal particles is/are chemically modified with a modifying group capable of imparting a charge, and the immobilization step can be performed by eliminating ions in the dispersions of the colloidal particles, which exist between the substrate and the opposed plate. The ion elimination facilitates electrostatic adsorption of the colloidal particles onto the substrate.

As a method for eliminating ions in the dispersions of the colloidal particles, for example, ion elimination can be performed by placing an ion exchange resin around the substrate and the opposed plate to adsorb ions, or by immersing the substrate and the opposed plate in pure water to diffuse ions existing between the substrate and the opposed plate through diffusion or convection.

In addition, as another method for performing the immobilization step, it is also possible to adopt a method of changing a pH value in the dispersion of the colloidal particles existing between the substrate and the opposed plate to change a magnitude or a sign of a surface charge of the colloidal particles or the substrate, thereby electrostatically adsorbing the colloidal particles with the signs of the surface charges of the colloidal particles and the substrate being opposite. For example, aminopropyltriethoxysilane (APTES) as a silane coupling agent has an amino group which is a weak base, and is positively charged at a pH of <7.8. Silica has a silanol group which is a weak acid group, and therefore is negatively charged. A glass substrate surface-modified with APTES is negatively charged at a pH of about 7 or more and positively charged at a pH of below 7 (see Aoyama, Y.; Toyotama, A.; Okuzono, T.; and Yamanaka, J., Langmuir, 2019, 135 (28), 9194-9201). In this way, the negatively charged colloidal particles can be electrostatically adsorbed onto the substrate by positively charging the substrate that is initially negatively charged. As a method for reducing the pH in the dispersion of the colloidal particles, for example, a method can be adopted in which the substrate and the opposed plate are immersed in an aqueous solution of hydrochloric acid, and the hydrochloric acid is guided to the colloidal dispersion through diffusion or convection.

### BRIEF DESCRIPTION OF DRAWINGS

FIG. 1 is a schematic diagram of a colloidal crystal of Embodiment 1.

FIG. 2 is a step chart showing steps for producing the colloidal crystal of Embodiment 1.

FIG. 3 is a schematic diagram of a colloidal crystal (a) having a four-fold symmetric pattern and a colloidal crystal (b) having a six-fold symmetric pattern.

FIG. 4 is a phase diagram obtained from theoretical calculation.

FIG. 5 is a schematic diagram of a colloidal crystal of Embodiment 2.

FIG. 6 is a step chart showing steps for producing the colloidal crystal of Embodiment 2.

FIG. 7 is a schematic diagram of a colloidal crystal (a) of Embodiment 3 and a colloidal crystal (b) when a substrate 1 on which the colloidal crystal of Embodiment 3 is formed is immersed in a dispersion medium having the same refractive index as that of colloidal particles 13b of a second layer.

FIG. 8 is a cross-sectional view showing a colloidal crystal preparation cell 20 and its periphery.

FIG. 9 shows three-dimensional images of colloidal crystals obtained by LSM.

FIG. 10 is a phase diagram obtained from the three-dimensional images.

FIG. 11 shows microscopic images for Example 1 and radial distribution functions calculated from the image (upper side: the microscopic image and the radial distribution function of the four-fold symmetric pattern colloidal crystal, and lower side: the microscopic image and the radial distribution function of the six-fold symmetric pattern colloidal crystal).

FIG. 12 shows microscopic images of colloidal crystals for Example 2 (left side: the four-fold symmetric pattern colloidal crystal, and right side: the six-fold symmetric pattern colloidal crystal).

FIG. 13 shows microscopic images of colloidal crystals for Example 3 (left side: the four-fold symmetric pattern colloidal crystal, and right side: the six-fold symmetric pattern colloidal crystal).

FIG. 14 shows microscopic images of colloidal crystals for Example 4 (left side: the four-fold symmetric pattern colloidal crystal, and right side: the six-fold symmetric pattern colloidal crystal).

FIG. 15 shows a microscopic image of colloidal crystals for Example 5.

FIG. 16 shows a microscopic image of colloidal crystals for Example 6.

FIG. 17 is an adsorption curve due to a decrease in base concentration in a constrained space (bars show standard deviations in experimental values and curves show calculated values based on a diffusion equation for various initial ion concentrations C*).

FIG. 18 shows optical microscope images of layers of a colloidal crystal of Example 7.

FIG. 19 shows cross-sectional images obtained by a confocal optical microscope in a case where a medium is ethylene glycol and in a case where the medium is a water-ethylene glycol mixed solution adjusted to have the same refractive index as that of polystyrene of the second layer in the colloidal crystal of Example 7.

FIG. 20 is a schematic diagram showing that different colloidal crystals are formed by adjusting a ratio of a particle diameter to a length of a gap.

### DESCRIPTION OF EMBODIMENTS

Hereinafter, embodiments embodying the present invention will be described with reference to the drawings.

### Embodiment 1

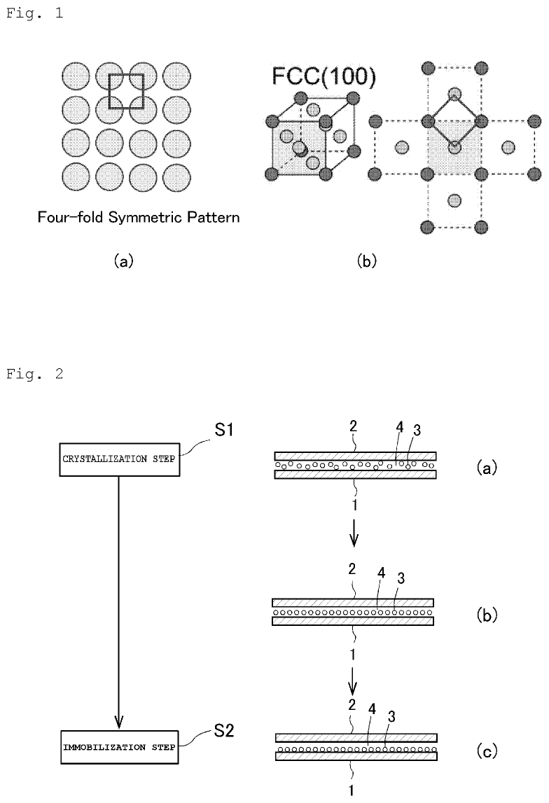

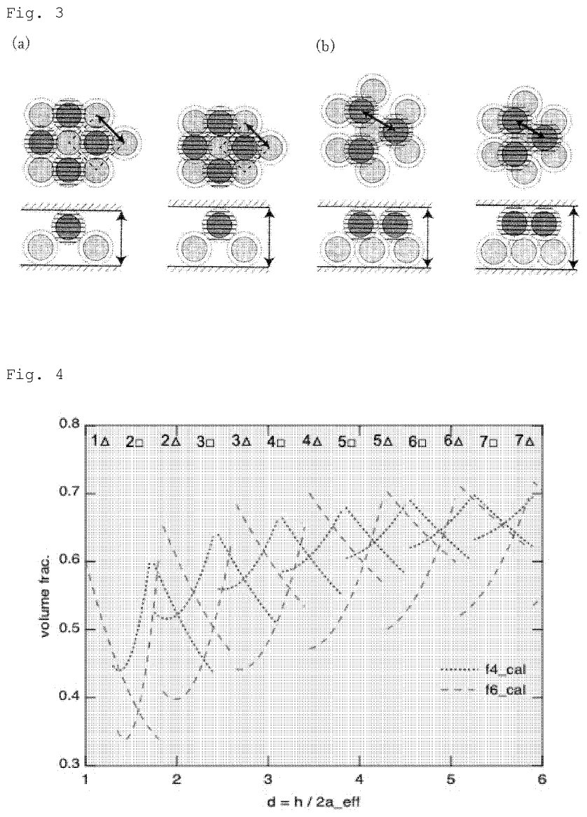

FIG. 1(a) shows a schematic diagram of a colloidal crystal having a four-fold symmetric pattern of Embodiment 1. This colloidal crystal is a two-dimensional colloidal crystal having a four-fold symmetric pattern, and is composed of a single layer of a (100) plane of FCC (face-centered cubic structure) (see FIG. 1(b)). Note that colloidal particles constituting the colloidal crystal are not in contact with each other, with a certain distance being maintained. This colloidal crystal can be produced by a series of steps (crystallization step S1 and immobilization step S2) shown in FIG. 2.

### (Crystallization Step S1)

A substrate 1 and an opposed plate 2 facing each other in parallel are provided, a dispersion of colloidal particles in which colloidal particles 3 are dispersed in a dispersion medium 4 is dropped onto the substrate 1, and then the opposed plate 2 is overlaid thereon (see FIG. 2(a)). The type of the colloidal particles 3 is not particularly limited, and inorganic particles (for example, SiO₂ particles, TiO₂ particles, and alumina particles), organic particles (for example, polystyrene particles and acrylic polymer particles), and metal particles (for example, noble metal particles such as Au particles, Pt particles, Pd particles, rhodium particles, iridium particles, ruthenium particles, osmium particles, and rhenium particles) can be used. As the dispersion of colloidal particles, commercially available particles for colloids can be dispersed in an appropriate dispersion medium such as water, inorganic particles synthesized by a sol-gel method or the like can be used, or particles having relatively uniform sizes obtained by polymerizing a monomer such as styrene by emulsion polymerization or the like can be used as the colloidal particles. Particles obtained by coating surfaces of non-metal particles with a metal (for example, ceramic or polymer particles with a noble metal such as Au) may be used as the colloidal particles.

Examples of the dispersion medium include water, but liquids other than water can also be used. For example, formamides (for example, dimethylformamide) and alcohols (for example, ethylene glycols) can be used. These may be mixed liquids with water.

The colloidal particles 3 in the dispersion of the colloidal particles between the substrate 1 and the opposed plate 2 form charged colloidal crystals over time (FIG. 2(b)). In this case, the type of the charged colloidal crystal to be formed varies depending on a ratio of a distance (gap) h between the substrate 1 and the opposed plate 2 to a particle diameter (=2a) of the colloidal particles 3. This is described in Non-Patent Literature 2 and can be derived from theoretical calculation. That is, the colloidal particles are assumed to be rigid bodies, and a (111) or (100) plane of the FCC structure is assumed to be taken so that a density of the colloidal particles in a constrained space is maximized. In addition, an interaction between the colloidal particles is calculated by consideration of only rigid sphere potential and further approximation with a high-pressure limit in which a pressure p depends only on a size h of the gap as shown in Equation (1).

$$[ Math . 1 ]$$

$$p = g Δμ {\int }_{0}^{h} ρ dz = g Δμ \overline{ρ} h \qquad ( 1 )$$

In the equation, g is gravitational acceleration, Δμ is a density difference between the colloidal particles and the dispersion medium, and p is a volume fraction of the colloidal particles. In this model, a four-fold symmetric pattern and a six-fold symmetric pattern are subjected to geometrical calculation to determine the volume fractions. An inter-particle distance is r, a radius of the colloidal particles is a, and d equals to r/2a. A schematic diagram of the four-fold symmetric pattern is shown in FIG. 3. In the same layer, when the inter-particle distance is larger than the particle diameter, particles in different layers are in contact with each other but particles in the same layer are not in contact with each other (FIG. 3(a)). On the other hand, in the same layer, when the inter-particle distance is equal to the particle diameter (FIG. 3(a)), dn□ is determined by the following equation (2). A maximum filling rate of the colloidal particles is 0.74.

$$[ Math . 2 ]$$

$${d}_{n} = 1 + ( n - 1 ) / \sqrt{2} \qquad ( 2 )$$

In the equation, □ denotes the four-fold symmetric pattern. As a result, a volume fraction ρn□ of the colloidal particles in the case of forming the four-fold symmetric pattern can be determined by the following equation (3).

$$[ Math . 3 ]$$

$$d < {d}_{n} ; {ρ}_{n} = \frac{π}{6} {\frac{n}{d} [ \frac{2 - {( d - 1 )}^{2}}{{( {d}_{n} - 1 )}^{2}} ]}^{- 1} \\ d = {d}_{n} ; {ρ}_{n}^{*} = \frac{π}{6} \frac{n}{{d}_{n}} = {\frac{π \sqrt{2}}{6} [ 1 + \frac{\sqrt{2} - 1}{n} ]}^{- 1} < 0.74 \\ d \geq {d}_{n} ; {ρ}_{n} = \frac{π}{6} \frac{n}{d} \qquad ( 3 )$$

Similarly, in the six-fold symmetric pattern, in the same layer, when the inter-particle distance is larger than the colloidal particle diameter, colloidal particles in different layers are in contact with each other, but particles in the same layer are not in contact with each other (FIG. 3(b)). In the same layer, when the inter-particle distance is equal to the colloidal particle diameter (FIG. 3(b)), d(nΔ) is expressed by the following equation (4). In the equation, Δ denotes the six-fold symmetric pattern.

$$[ Math . 4 ]$$

$${d}_{n Δ} = 1 + ( n - 1 ) \sqrt{2 / 3} \qquad ( 4 )$$

As a result, a volume fraction ρnΔ of the colloidal particles in the case of forming the six-fold symmetric pattern can be determined by the following equation (5).

$$[ Math . 5 ]$$

$$d < {d}_{n Δ} ; {ρ}_{n Δ} = \frac{π}{6} {\frac{2 n}{3 \sqrt{3} d} [ 1 - \frac{{( d - 1 )}^{2}}{{( n - 1 )}^{2}} ]}^{- 1} \\ d = {d}_{n Δ} ; {ρ}_{n Δ}^{*} = \frac{π}{6} \frac{2 n}{\sqrt{3} {d}_{n Δ}} = {\frac{π \sqrt{2}}{6} [ 1 + \frac{\sqrt{\frac{2}{3}} - 1}{n} ]}^{- 1} < 0.74 \\ d \geq {d}_{n Δ} ; {ρ}_{n Δ} = \frac{π}{6} \frac{2 n}{\sqrt{3} d} \qquad ( 5 )$$

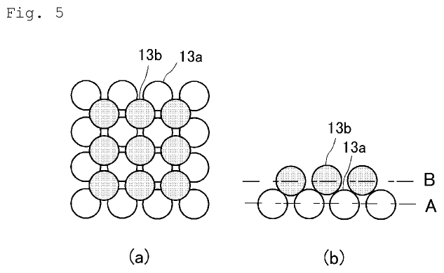

From Equations (3) and (5), graphs plotting possible volume fractions determined by changing a size ratio d are shown in FIG. 4. Dotted lines with fine spacing indicate a volume fraction change with respect to d of the four-fold symmetric pattern, and dotted lines with rough spacing indicate a volume fraction change with respect to d of the six-fold symmetric pattern. The higher the particle density, the more stable the crystal structure is. Therefore, a phase diagram (see FIG. 4) is obtained by color-coding at a place where the crystal structure having a high colloidal particle density changes between the four-fold symmetric pattern and the six-fold symmetric pattern.

From the above results, it can be seen that, as a value of h/2a increases, phase transitions occur in the order of a six-fold symmetric pattern formed of two layers (2Δ)→a four-fold symmetric pattern formed of three layers (3□)→a six-fold symmetric pattern formed of three layers (3Δ)→a four-fold symmetric pattern formed of four layers (4□)→a six-fold symmetric pattern formed of four layers (4Δ). Therefore, by keeping the substrate 1 and the opposed plate 2 parallel and h/2a at a ratio so as to attain a four-fold symmetric pattern, a colloidal crystal having a four-fold symmetric pattern is formed. Even if the substrate 1 and the opposed plate 2 are not parallel but inclined, or the substrate 1 and the opposed plate 2 are deflected and thus the value of h/2a changes depending on the location, it is possible to partially form a four-fold symmetric pattern.

Since the state of the surface charge of a colloidal crystal changes due to the presence of a minor amount of salt (ionic impurity), colloidal crystal formation may be inhibited. Therefore, the dispersion medium is preferably sufficiently desalinated in the preparation of the dispersion of colloidal particles. For example, in the case of using water, first, dialysis is performed on purified water until an electric conductivity of water used is about the same as the value before use, and then desalination purification is performed by keeping a sufficiently washed ion exchange resin (mixed bed of cation and anion exchange resins) coexisting in a sample for at least one week. However, after desalination purification is performed in this way, salts may be intentionally added, and desalination is performed in a crystallization step S2 which will be described later to precipitate colloidal crystals.

It is also necessary to consider the particle diameter and distribution of the colloidal particles. The particle diameter of the colloidal particles is preferably 600 nm or less, and more preferably 300 nm or less. This is because, in the case of colloidal particles having a large particle diameter exceeding 600 nm, the colloidal particles are likely to sediment due to influence of gravity, and stability of a dispersion of the colloidal particles is deteriorated. A coefficient of variation in particle diameter of the colloidal particles (that is, a value obtained by dividing a standard deviation of the particle diameter by an average particle diameter) is preferably within 20%, more preferably 10% or less, and most preferably 5% or less. This is because, when the coefficient of variation in particle diameter increases, it becomes difficult for the colloidal crystals to precipitate, lattice defects and nonuniformity of the colloidal crystals increase, and it becomes difficult to obtain high-quality colloidal crystals.

Materials for the substrate 1 and the opposed plate 2 are not particularly limited, and, for example, a smooth glass plate, ceramic plate, plastic plate, metal plate, or the like can be used.

### (Immobilization Step S2)

The precipitated charged colloidal crystal having a four-fold symmetric pattern is electrostatically adsorbed and fixed (see FIG. 2(c)). As a method for immobilization, a method can be adopted in which a surface of the substrate 1 or surfaces of the colloidal particles 3 is/are modified with a silane coupling agent having an amino group or the like, and an alkali such as NaOH, sodium hydrogen carbonate, or sodium carbonate is added to the dispersion medium. In this case, it is possible to employ a method in which the substrate 1 and the opposed plate 2 are immersed in water, and cations existing between the substrate 1 and the opposed plate 2 are removed through diffusion or convection. In this case, when an ion exchange resin is placed in water in which the substrate and the opposed plate are to be immersed, cations can be removed more quickly. Since the pH of the dispersion of the colloidal particles is lowered by the removal of the cations, and the amino group is ionized, the charged colloidal crystal with a four-fold symmetric pattern formed of one layer can be immobilized on the surface of the substrate 1 by electrostatic attractive force with the colloidal particles 3 or the substrate 1 in which the amino group having a negative surface charge is not chemically modified. The charged colloidal crystal thus obtained is adsorbed onto the substrate 1 by electrostatic attractive force, and is stably immobilized without moving even when immersed in pure water.

### Embodiment 2

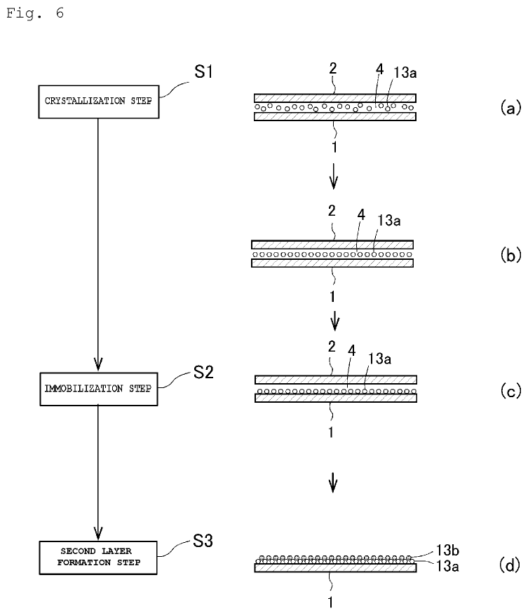

As shown in FIG. 5, the colloidal crystal of Embodiment 2 is composed of two layers, that is, a single layer A with a four-fold symmetric pattern formed of colloidal particles 13a spaced at a certain distance from each other, and a single layer B formed of colloidal particles 13b, which is located immediately above the center of a square unit lattice in the single layer A and stacked in contact with four colloidal particles 13a of the single layer A. This colloidal crystal can be produced according to the step chart shown in FIG. 6. First, the crystallization step S1 and the immobilization step S2 shown in Embodiment 1 are performed to form a colloidal crystal having a four-fold symmetric pattern formed of a single layer on the substrate 1. Then, the opposed plate 2 is removed, the substrate 1 is immersed in pure water to wash away the attached dispersion medium, and then a dispersion of the colloidal particles 13b having a charge opposite to that of the colloidal particles 13a is brought into contact with the single layer of the colloidal particles 13a to electrostatically adsorb a second layer formed of the colloidal particles 13b onto a first layer formed of the colloidal particles 13a (second layer formation step S3). At this time, the colloidal particles 13b are disposed immediately above the center of a square crystal lattice formed of the colloidal particles 13a while being in contact with the colloidal particles 13a by electrostatic attractive force. In this way, it is possible to obtain a colloidal crystal with a four-fold symmetric pattern, formed of two layers, i.e., the single layer A and the single layer B formed of the colloidal particles 13b stacked in contact with the four colloidal particles 13a of the single layer A, as shown in FIG. 5.

As the colloidal particles 13b having a charge opposite to that of the colloidal particles 13a, for example, in a case where the colloidal particles 13a have a negative surface charge (for example, silica), silica whose surface is modified with a silane coupling agent having an amino group or the like can be used. In a case where the colloidal particles 13a have a positive surface charge (for example, silica modified with a silane coupling agent having an amino group or the like), the colloidal particles 13b used can be unmodified silica with a negative surface charge which is not surface-modified, silica modified with a polymer having a negative surface charge or the like, or polystyrene having a negative surface charge.

### Embodiment 3

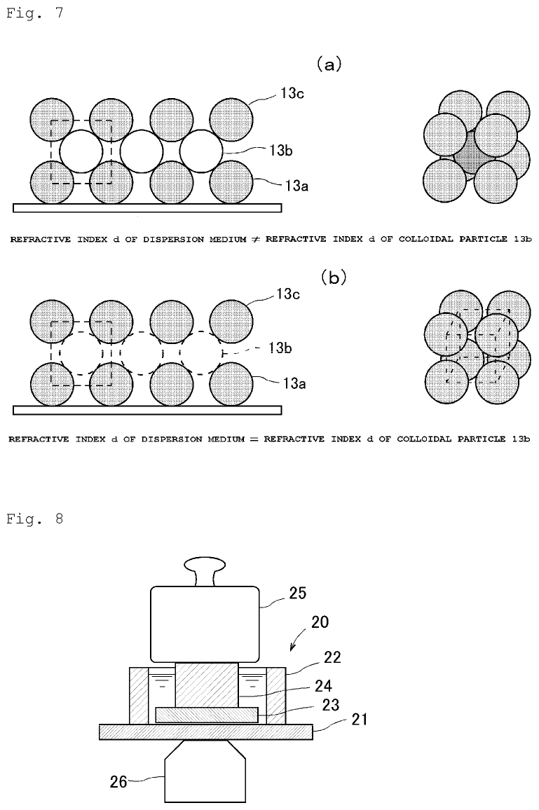

The colloidal crystal of Embodiment 3 is a colloidal crystal in which colloidal particles of a third layer are further stacked on the colloidal crystal formed of two layers of Embodiment 2. First, a colloidal crystal with a four-fold symmetric pattern formed of two layers is formed by the method of Embodiment 2. Then, the opposed plate 2 is removed, the substrate 1 is immersed in pure water to wash away the attached dispersion medium, and then a dispersion of colloidal particles 13c having a charge opposite to that of the colloidal particles 13b is brought into contact with the layer of the colloidal particles 13b to electrostatically adsorb the colloidal particles 13c onto the second layer, thereby forming a third layer (third layer formation step S4). In this way, a colloidal crystal having a four-fold symmetric pattern in which three layers are stacked can be obtained (see FIG. 7(a)).

Further, the substrate 1 on which the colloidal crystal of Embodiment 3 has been formed is immersed in a dispersion medium having the same refractive index as that of the colloidal particles 13b of the second layer (the colloidal crystal is shifted from the state in FIG. 7(a) to that in FIG. 7(b)), so that the colloidal particles 13b become optically transparent. Therefore, the colloidal crystal is formed only of the first layer and the third layer from the optical viewpoint (see FIG. 7(b)).

### EXAMPLES

### 1) Preparation of Colloidal Dispersion

An aqueous dispersion of silica particles (KEP-50: average particle diameter=0.53 μm, charge number Z=−6420, coefficient of variation in particle diameter=5%; and KEP-100: average particle diameter=1.1 μm, Z=−19488, coefficient of variation in particle diameter=5%, both manufactured by Nippon Shokubai Co., Ltd.) was provided as a colloidal dispersion. Furthermore, a colloidal dispersion to which a predetermined amount of Na₂CO₃ or NaOH was added was provided. Thus, the colloidal dispersions used in Examples 1 to 4 were provided.

Example 1: (KEP-50) Volume fraction of silica particles=0.3, NaOH concentration: 50 mM

Example 2: (KEP-50) Volume fraction of silica particles=0.1, Na₂CO₃ concentration: 0.1 mM

Example 3: (KEP-50) Volume fraction of silica particles=0.2, Na₂CO₃ concentration: 1 mM

Example 4: (KEP-100) Volume fraction of silica particles=0.3, no alkali added

### 2) Preparation of Colloidal Crystal Preparation Cell

### Washing of Cover Glass

An optical microscope cover glass (35 mm×55 mm×0.15 mm, manufactured by Matsunami Glass Ind., Ltd.) was provided, and the front surface and the back surface of the cover glass were subjected to UV irradiation and ozone treatment for 10 minutes each using an ASM401N-type UV ozone treatment apparatus manufactured by ASUMI GIKEN, Limited (hereinafter, abbreviated as UV/O₃ treatment). Thereafter, the cover glass was immersed in a concentrated HCl+MeOH mixed liquid (volume ratio: 1:1) for 30 minutes, washed with Milli-Q water, immersed in concentrated sulfuric acid for 2 hours, and then washed well with Milli-Q water. Note that the Milli-Q water is ultrapure water obtained by a Milli-Q (registered trademark) water production apparatus manufactured by Merck.

Surface Modification of Cover Glass with APTES

The cover glass thus washed was immersed in a solution (hereinafter, abbreviated as APTES solution) in which 3-aminopropyltriethoxysilane (APTES) was dissolved in 90% EtOH so as to attain a 1 vol. % solution, and left at room temperature for 1 hour. Thereafter, the cover glass was pulled up, dried in an oven at 70° C. overnight, and the silanol group on the glass surface was chemically modified with APTES. Further, the cover glass was shaken in Milli-Q water overnight to be washed, and then dried.

### Preparation of Colloidal Crystal Preparation Cell 20

As a cell for precipitating a colloidal crystal, a colloidal crystal preparation cell 20 shown in FIG. 8 was prepared. In this cell, a silicone sheet 22 having a thickness of 5 mm and provided with square holes of 2 cm×2 cm is adhered to a cover glass 21 chemically modified with APTES.

### 3) Colloidal Crystallization Step S1

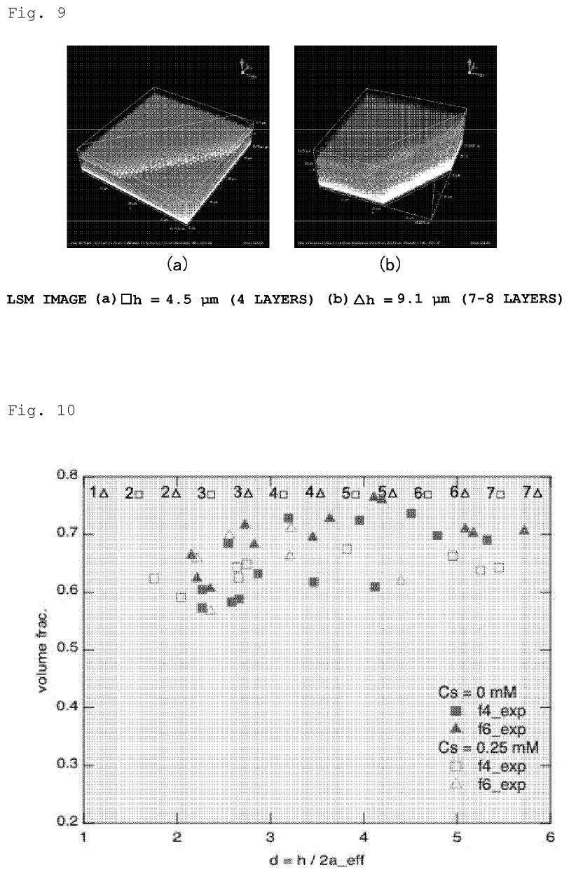

Into a recess formed by the square hole in the silicone sheet 22 and the cover glass 21, 500 μL of the colloidal dispersion was dropped. Then, a cover glass 23 was overlaid on the inner side of the square hole, a quartz glass 24 was placed thereon, a weight 25 of 100 g was further placed thereon, the cell was allowed to stand for 30 minutes, and then an objective lens 26 of a confocal laser microscope was brought close to the lower side of the cover glass 21 for observation. That is, the colloidal dispersion was set in the colloidal crystal preparation cell 20, which was allowed to stand for 30 minutes or longer, and then a three-dimensional image was acquired by a laser scanning microscope (LSM) (see FIG. 9). A size h of a gap and a number Nn of particles in each layer were determined from LSM image analysis, and a volume fraction p was determined. However, since a charged colloid system was used, an effective radius (a_{eff}) of the particles was determined from the volume fraction by Equation (6) to perform correction. Using the a_{eff} thus obtained, an apparent volume fraction was calculated to create the phase diagram shown in FIG. 10 (d=h/2a_{eff}).

$$[ Math . 6 ]$$

$${a}_{eff} = a + \frac{1}{2} {\int }_{2 a}^{σ} [ 1 - exp ( \frac{- u ( r )}{{k}_{B} T} ) ] dr \qquad ( 6 )$$

In the equation, a is a particle radius, u(r) is an interaction potential between two particles (u(σ)=0), k_{B} is a Boltzmann constant, and T is an absolute temperature. As shown in FIG. 10, the experimental results corrected were superimposed onto a theoretical phase diagram and compared. A square symbol indicates a four-fold symmetric pattern, and a triangle symbol indicates a six-fold symmetric pattern. In addition, a black symbol indicates a case where no salt was added, and a white symbol indicates a case where NaCl was added (NaCl concentration Cs=0.25 mM). As a result, it could be confirmed that the experimental results were consistent in tendencies with the theoretical phase diagram. In addition, it was shown that the correction of the effective radius is useful because the tendencies were consistent by the same correction regardless of whether salt addition was performed or not. The reason why the four-fold symmetric pattern and the six-fold symmetric pattern overlap with each other when d is a small value is considered to be the accuracy limit of LSM. The LSM images were scanned at 0.15 μm/step, and it is considered that the smaller the gap was, the larger the error was. In addition, the reason why the value of p was small when the value of d was large is considered to be that an error occurred in counting of the number of particles because the image is blurred more as the total number is large.

As described above, the phase behavior of the crystal structures in the constrained space could be confirmed by the three-dimensional image analysis by LSM. That is, it could be confirmed that the phase transition of 2Δ→3□→3Δ→4□→4Δ → . . . occurred as the size h of Gap increased. In addition, using an optical microscope, it was observed that the weight was removed from the four-fold symmetric pattern and that the structure transitioned to the six-fold symmetric pattern. In the experiments with Cs=0.050 mM and 0.10 mM, it was shown that the same tendencies were obtained.

### 4) Immobilization Step S2

From above the colloidal crystal preparation cell 20, 1.5 g of an ion exchange resin (mixed bed of cation and anion exchange resins, AG501 X-8(D) manufactured by Bio-Rad Laboratories, Inc.) was charged. Then, in order to prevent evaporation of water, the colloidal crystal preparation cell 20 was covered with a plastic container (not shown) and allowed to stand for several days. Then, it was confirmed by microscopic observation that silica particles were adsorbed onto the cover glass 21 as a substrate, and then the weight 25, the quartz glass 24, and the cover glass 23 were removed. Thereafter, the cover glass 21 was sufficiently washed with Milli-Q water, and a microscopic image of the adsorbed silica particles was taken in a state where a sufficient amount of water was further added. The microscopic image thus obtained was analyzed using image analysis software Image J, an average distance r between the particle centers was determined, and a volume fraction φᵥ was calculated from Equation (7) (wherein a represents a radius of the silica particles.). In addition, a radial distribution function g(r) of the particles was determined from a binarized image obtained by binarizing the image into black and white using the image processing software Image J.

$$[ Math . 7 ]$$

$$ϕ v = \frac{( 4 \sqrt{2} )}{3} {π ( \frac{a}{r} )}^{3} \qquad ( 7 )$$

### Result

### 1) Regarding Example 1

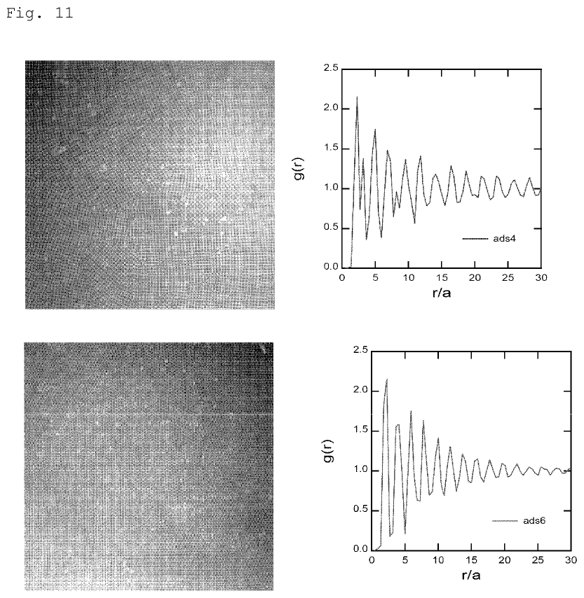

FIG. 11 shows microscopic images for Example 1 using a colloidal dispersion having a volume fraction of silica particles=0.3 and a NaOH concentration of 50 mM and radial distribution functions calculated from the images. Here, the reason why two microscope images (both image sizes are 50 μm×50 μm) are shown is that, since the gap distance varies due to the deflection of the cover glasses 21 and 23, a colloidal crystal having a four-fold symmetric pattern (upper left in FIG. 11) or a colloidal crystal having a six-fold symmetric pattern (lower left in FIG. 11) is formed (the same applies to Examples 2 to 4). In the colloidal crystal having a four-fold symmetric pattern, an inter-particle distance r was determined to be 623±7 nm (volume fraction φᵥ,4=0.46) from the microscopic image thereof. In addition, in the colloidal crystal having a six-fold symmetric pattern, r was determined to be 600±24 nm (φᵥ,6=0.51).

### 2) Regarding Example 2

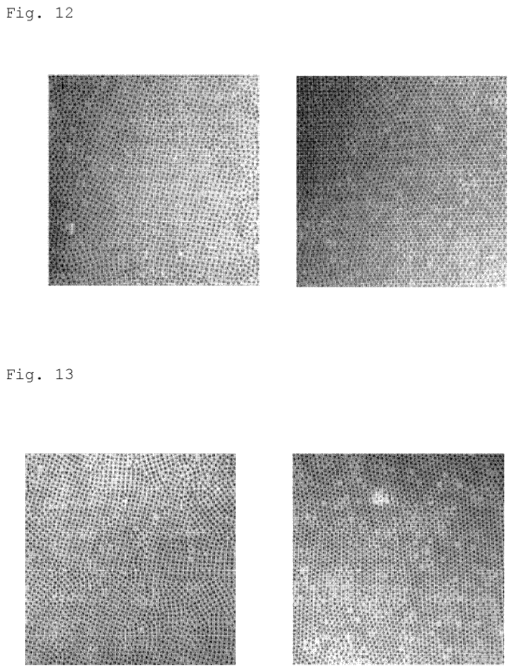

FIG. 12 shows microscopic images for Example 2 using a colloidal dispersion having a volume fraction of silica particles=0.1 and a Na₂CO₃ concentration of 0.1 mM (image size: 30 μm×30 μm). In the colloidal crystal having a four-fold symmetric pattern, the inter-particle distance r was determined to be 695±13 nm (φᵥ₄=0.33) from the microscopic image thereof. In addition, in the colloidal crystal having a six-fold symmetric pattern, r was determined to be 690±25 nm (φᵥ₆=0.34).

### 2) Regarding Example 3

FIG. 13 shows microscopic images for Example 3 using a colloidal dispersion having a volume fraction of silica particles=0.2 and a Na₂CO₃ concentration of 1 mM (image size: 30 μm×30 μm). In the colloidal crystal having a four-fold symmetric pattern, the inter-particle distance r was determined to be 644±15 nm (φᵥ₄=0.41) from the microscopic image thereof. In addition, in the colloidal crystal having a six-fold symmetric pattern, r was determined to be 638±8 nm (φᵥ₆=0.42).

### 2) Regarding Example 4

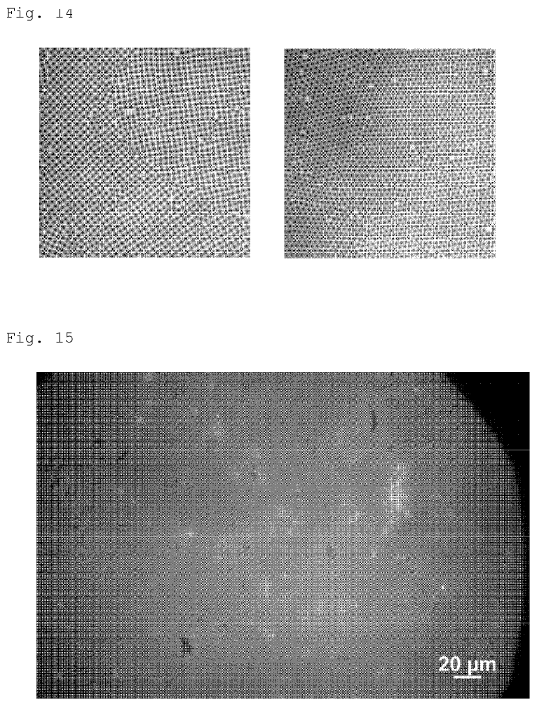

FIG. 14 shows microscopic images for Example 4 using a colloidal dispersion having a volume fraction of silica particles=0.3 and not added with alkali (image size: 50 μm×50 μm). In the colloidal crystal having a four-fold symmetric pattern, the inter-particle distance r was determined to be 1.244±0.019 μm (φᵥ₄=0.49) from the microscopic image thereof. In addition, in the colloidal crystal having a six-fold symmetric pattern, r was determined to be 1.269±0.010 μm (φᵥ₆=0.46).

From the microscopic images for Examples 1 to 4 and the radial distribution functions obtained from the microscopic images, it has been found that various parameters of the formed colloidal crystals having a four-fold symmetric pattern or a six-fold symmetric pattern can be controlled by the particle diameter or the particle concentration of the colloidal particles.

In Examples 1 to 4, the reason why the structure of the colloidal crystal varies depending on the location is considered to be that the distance of the gap varies due to the deflection of the cover glasses 21 and 23 and non-uniformity of weighting by the weight. By replacing the thin cover glass with a glass block so as to make the distance of the gap uniform, or by adopting a structure in which a load is uniformly applied, it is possible to make control so that all colloidal crystals have a four-fold symmetric pattern or have a six-fold symmetric pattern.

### Example 5

### 1) Preparation of Colloidal Dispersion

In Example 5, an aqueous dispersion of polystyrene particles (manufactured by Thermo, average particle diameter=600 nm, negatively charged, zeta potential=−48 mV) was concentrated under reduced pressure, and then an aqueous solution of NaOH was added to obtain a colloidal dispersion having a particle concentration of 40 vol % and a NaOH concentration of 4 mM.

### 2) Colloidal Crystal Preparation Cell

The colloidal crystal preparation cell used is the same as the cell used in Examples 1 to 4, and the description thereof is omitted.

### 3) Colloidal Crystallization Step S1

Next, the same colloidal crystallization step S1 as in Examples 1 to 4 was performed. However, the amount of the colloidal dispersion dropped into the recess was 176 μL.

### 4) Immobilization Step S2

Further, the same immobilization step S2 as in Examples 1 to 4 was performed. However, the time for desalination with the ion exchange resin was set to 24 hours. When the glass substrate was microscopically observed, colloidal crystals having a four-fold symmetric pattern and formed of a single layer of polystyrene particles were confirmed, as shown in FIG. 15. The glass substrate on which the four-fold symmetric colloidal crystals were formed was stored in pure water.

### Example 6

### 1) Preparation of Colloidal Dispersion

Example 6 is the same as Example 5 except that the NaOH concentration of the colloidal dispersion was 5 mM, and the description thereof is omitted.

### 2) Colloidal Crystal Preparation Cell

The colloidal crystal preparation cell used is the same as the cell used in Example 5, and the description thereof is omitted.

### 3) Colloidal Crystallization Step S1

Next, the same colloidal crystallization step S1 as in Example 5 was performed. However, the amount of the colloidal dispersion dropped into the recess was 206 μL.

### 4) Immobilization Step S2

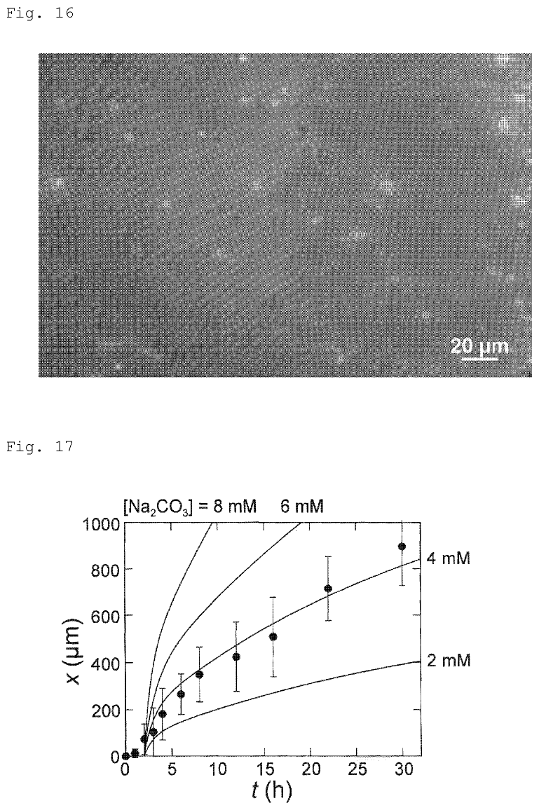

Further, the same immobilization step S2 as in Example 5 was performed. When the glass substrate was microscopically observed, colloidal crystals having a four-fold symmetric pattern and formed of a single layer of polystyrene particles were confirmed, as shown in FIG. 16. The glass substrate on which the colloidal crystals were formed was stored in pure water.

### <Adsorption Curve of Colloidal Crystal Having Four-Fold Symmetric Pattern>

An experimental value of an adsorption curve of a colloidal crystal having a four-fold symmetric pattern was determined by the following procedures and compared with a calculated value derived from theory.

### 1) Preparation of Colloidal Silica Particle Dispersion

An aqueous dispersion of silica particles (KEP-50: average particle diameter=0.53 μm, charge number Z=−6420, coefficient of variation in particle diameter=5%; and KEP-100: average particle diameter=1.1 μm, Z=−19488, coefficient of variation in particle diameter=5%, both manufactured by Nippon Shokubai Co., Ltd.) was provided as a colloidal dispersion. Further, a predetermined amount of Na₂CO₃ was added to prepare a colloidal silica particle dispersion (volume fraction of silica particles=0.3, Na₂CO₃ concentration=10 mM).

### 2) Preparation of Colloidal Crystal Preparation Cell

### Washing of Cover Glass

An optical microscope cover glass (35 mm×55 mm×0.15 mm, manufactured by Matsunami Glass Ind., Ltd.) was provided, and the front surface and the back surface of the cover glass were subjected to UV irradiation and ozone treatment for 10 minutes each using an ASM401N-type UV ozone treatment apparatus manufactured by ASUMI GIKEN, Limited (hereinafter, abbreviated as UV/O₃ treatment). Thereafter, the cover glass was immersed in a concentrated HCl+MeOH mixed liquid (volume ratio: 1:1) for 30 minutes, washed with Milli-Q water, immersed in concentrated sulfuric acid for 2 hours, and then washed well with Milli-Q water.

Surface Modification of Cover Glass with APTES

The cover glass thus washed was immersed in a solution (hereinafter, abbreviated as APTES solution) in which 3-aminopropyltriethoxysilane (APTES) was dissolved in 90% EtOH so as to attain a 1 vol. % solution, and left at room temperature for 1 hour. Thereafter, the cover glass was pulled up, dried in an oven at 70° C. overnight, and the silanol group on the glass surface was chemically modified with APTES. Further, the cover glass was shaken in Milli-Q water overnight to be washed, and then dried.

### Preparation of Colloidal Crystal Preparation Cell

In order to prepare colloidal crystals, the same cell as the colloidal crystal preparation cell 20 used in Examples 1 to 3 was used (see FIG. 8). In this cell, a silicone sheet 22 having a thickness of 5 mm and provided with square holes of 2 cm×2 cm is adhered to a cover glass 21 chemically modified with APTES.

### 3) Colloidal Crystallization Step S1

Into a recess formed by the square hole in the silicone sheet 22 and the cover glass 21, 500 μL of the colloidal dispersion was dropped. Then, a cover glass 23 was overlaid on the inner side of the square hole, a quartz glass 24 was placed thereon, a weight 25 of 100 g was further placed thereon, the cell was allowed to stand for 30 minutes, and then an objective lens 26 of a confocal laser microscope was brought close to the lower side of the cover glass 21 for observation. That is, the colloidal dispersion was set in the colloidal crystal preparation cell 20, which was allowed to stand for 30 minutes or longer, and then a three-dimensional image was acquired by a laser scanning microscope (LSM). It was confirmed that colloidal crystals having a four-fold symmetric pattern were formed.

### 4) Immobilization Step S2

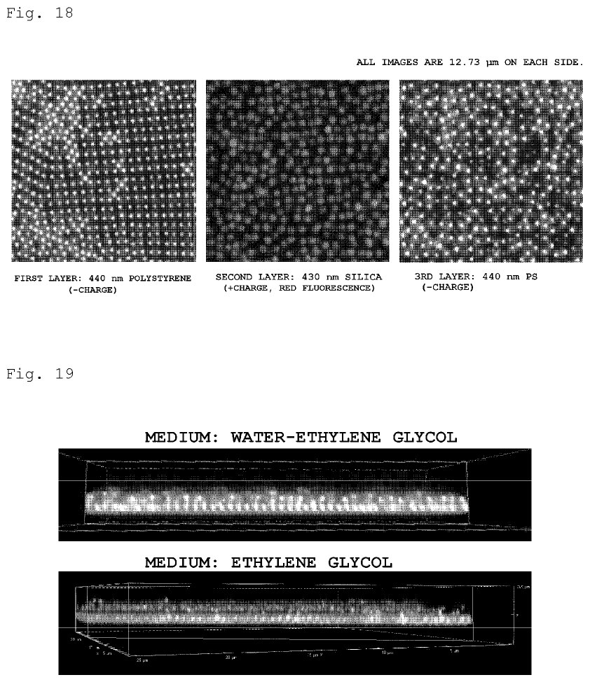

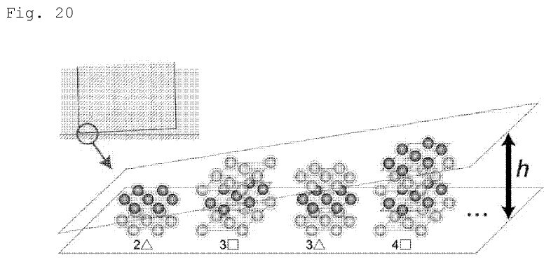

From above the colloidal crystal preparation cell 20, 1.5 g of an ion exchange resin (mixed bed of cation and anion exchange resins, AG501 X-8(D) manufactured by Bio-Rad Laboratories, Inc.) was charged. Then, in order to prevent evaporation of water, the colloidal crystal preparation cell 20 was covered with a plastic container (not shown). A state where a single layer of colloidal crystals having a four-fold symmetric pattern as silica particles was adsorbed onto the cover glass 21 as a substrate was observed with a confocal laser microscope at predetermined time intervals to determine the length from a peripheral edge of the cover glass 21 to a growth end of the single layer of the four-fold symmetric colloidal crystals growing. The results are shown in FIG. 17. Data are average values of three experimental results, bars indicate standard deviations. As a result, it was found that ions were diffused outward from the peripheral edge of the cover glass 21 after addition of the ion exchange resin beads, thus that electrostatic adsorption proceeded inward from the peripheral edge of the cover glass 21 so that the single-layered colloidal crystals grew, and that, after 30 hours, the crystal size reached 1 mm.

5) Adsorption Curve Determined from Theoretical Calculation

The adsorption process is considered to be due to one-dimensional unidirectional diffusion of a base. An ion concentration C(x, t) (x and t are position and time, respectively) is given by Diffusion Equation (8). In the equation, D is an apparent diffusion coefficient of the ions (=1.16×10-5 cm2/s).

$$[ Math . 8 ]$$

$$\frac{\partial C}{\partial t} = D \frac{{\partial }^{2} C}{\partial {x}^{2}} \qquad ( 8 )$$

In addition, the ion concentration at an arbitrary position and an arbitrary time is given by Equation (9). In the equation, Ci is an initial value of a salt concentration, and erf is an error function. However, it is assumed that the ion exchange resin has a sufficiently high exchange capacity that satisfies C=0 at x=0.

$$[ Math . 9 ]$$

$$C = {C}_{i} [ 1 - erf ( \frac{x}{\sqrt{Dt}} ) ] \qquad ( 9 )$$

By Equation (9), (x, t) was calculated for various C=C* values with Cᵢ=10 mM. The results are shown in FIG. 17. The experimental values were well consistent with the calculated values determined from the diffusion equation when C=4 mM was set. This result suggested that electrostatic adsorption occurs at C*=about 4 mM.

### <Preparation of Colloidal Crystal Formed of a Plurality of Layers>

### Example 7

In Example 7, a colloidal crystal composed of three layers and having a four-fold symmetric pattern was prepared. Details of the preparation will be described below.

### 1) Formation of First Layer

An aqueous dispersion of polystyrene particles (Thermo, coefficient of variation in particle diameter=4%, negatively charged, zeta potential=−48 mV) having a diameter of 440 nm was concentrated and used. An aqueous solution of NaOH was added to the aqueous dispersion to set the particle concentration to 33 vol % and the NaOH concentration to 1 mM. A square plastic frame (inner dimensions: 20 mm×20 mm) was provided on the surface of the APTES-modified glass, and 300 μL of the dispersion was dropped onto the APTES-modified glass substrate thus configured to be able to be filled with a liquid. Then, a plastic plate (15 mm×15 mm) was placed, and 1.5 g of an ion exchange resin (mixed bed of cation and anion exchange resins, Bio-Rad, AG501 X-8 (D)) was added to the peripheral edge of the plastic plate, and desalination was performed for 2 hours. After completion of the desalination treatment, the glass substrate was washed with water to remove excessive particles, the glass substrate was microscopically observed, and colloidal crystals having a four-fold symmetric pattern and formed of a single layer of polystyrene particles were confirmed. The glass substrate on which the colloidal crystals formed of the single layer were formed was stored in pure water.

### 2) Formation of Second Layer

A red fluorescent dye (rhodamine isothiocyanate) was adsorbed onto the surface of silica particles KE-P30 (particle diameter: 300 nm) manufactured by Nippon Shokubai Co., Ltd., and a silica coating layer was further formed by a sol-gel method. The silica particles whose outermost surface was thus covered with the silica coating layer were added to an ethanol solution of polyethyleneimine-based silane coupling (manufactured by Gelest) and treated, and an amino group was introduced into the silica coating layer to prepare positively charged red fluorescent silica particles having a particle diameter of 430 nm (coefficient of variation in particle diameter=4%). The zeta potential of the particles was measured and found to be +58 mv.

An aqueous dispersion (particle concentration=0.1%) of the positively charged red fluorescent silica particles was prepared, and a saline dispersion in which 200 μL of the aqueous dispersion was added to and dispersed in 3 mL of a 100 μM NaCl aqueous solution was added dropwise onto the glass substrate on which the first layer of colloidal crystals was formed. Then, a semipermeable membrane bag filled with an ion exchange resin was brought into contact with the glass substrate to perform a desalination treatment for 2 hours, and then the glass substrate was observed by LSM. As a result, it was confirmed that red fluorescent silica particles were adsorbed, in a single layer form, onto the colloidal crystals of polystyrene particles formed of a single layer. Further, the glass substrate was washed with water to remove an excessive dispersion, and then stored in pure water. In this way, a colloidal crystal in which a single layer of red fluorescent silica particles was stacked on a single layer of polystyrene particles having a four-fold symmetric pattern was obtained.

### 3) Formation of Third Layer

A saline dispersion obtained by adding and dispersing 2 μL of an aqueous dispersion (particle concentration=10 vol %) of negatively charged polystyrene particles having a diameter of 440 nm prepared in the formation of the first layer to/in a 100 μM NaCl aqueous solution (3 mL) was added dropwise onto the second layer. Then, the glass substrate was brought into contact with a semipermeable membrane bag filled with an ion exchange resin to perform a desalination treatment for 2 hours. Thereafter, the surface was microscopically observed, and it was confirmed that the polystyrene particles were adsorbed onto the red fluorescent silica particles. Finally, the glass substrate was washed with water to remove an excessive mixed liquid, and then stored in pure water. In this way, a colloidal crystal having a four-fold symmetric pattern in which a single layer of red fluorescent silica particles was stacked on a single layer of polystyrene particles and further a single layer of polystyrene particles was stacked thereon was obtained.

### (Microscopic Observation)

The colloidal crystal of Example 7 thus obtained was photographed with an optical microscope. As a result, as shown in FIG. 18, a four-fold symmetric pattern in which polystyrene particles were aligned at equal intervals was clearly observed from the microscopic image of the first layer. In addition, the red fluorescent silica particles of the second layer were located immediately above the center of the square unit lattice formed of the polystyrene particles of the first layer. Further, the polystyrene particles of the third layer were located immediately above the polystyrene particles of the first layer (see FIG. 19).

### <Replacement of Dispersion Medium in Colloidal Crystal of Example 7>

To the substrate 1 prepared in Example 7 and having colloidal crystals formed thereon, 3 mL of ethylene glycol was added, and the substrate was allowed to stand for 2 hours. In addition, 3 mL of a water-ethylene glycol mixed solution adjusted to have the same refractive index as the refractive index of the silica particles of the second layer was added instead of ethylene glycol, and the substrate was placed for 30 minutes. Then, an image of each of them was taken with a confocal laser scanning microscope (Nikon, C2 type). As a result, when the medium was ethylene glycol, the first layer, the second layer, and the third layer were clearly observed. On the other hand, when the water-ethylene glycol mixed solution adjusted to have the same refractive index as the refractive index of the silica particles of the second layer was used as the medium, the second layer became transparent and could not be observed.

The present invention is not limited to the description of the embodiments and examples of the invention. Various modifications that can be easily conceived by those skilled in the art without departing from the scope of the claims are also included in the present invention.

### INDUSTRIAL APPLICABILITY

The colloidal crystal of the present invention can be used as a photonic material corresponding to various wavelengths by selecting the diameter of the colloidal particles.

### REFERENCE SIGNS LIST

1 Substrate
2 Opposed plate
3, 13a, 13b, 13c Colloidal particle
4 Dispersion medium
S1 Crystallization step
S2 Immobilization step
S3 Second layer formation step
S4 Third layer formation step
Colloidal crystal preparation cell
21 Cover glass
22 Silicone sheet
23 Cover glass
24 Quartz glass
25 Weight
26 Objective lens

1. A colloidal crystal which exists in a geometrically unconstrained space and has a four-fold symmetric pattern.

2. The colloidal crystal according to claim 1, which is formed of a single layer.

3. The colloidal crystal according to claim 1, which is formed of a plurality of layers.

4. The colloidal crystal according to claim 3, wherein a first layer formed of first colloidal particles and a second layer formed of second colloidal particles are alternately repeated to form a multilayer structure, and a refractive index of the first colloidal particles or a refractive index of the second colloidal particles is the same as a refractive index of a dispersion medium.

5. A method for producing a colloidal crystal, the method comprising:
a crystallization step of filling a dispersion of first colloidal particles between a substrate and an opposed plate facing the substrate to precipitate a charged colloidal crystal with a four-fold symmetric pattern formed of the first colloidal particles; and
an immobilization step of electrostatically adsorbing and immobilizing, onto the substrate, a charged colloidal crystal with a four-fold symmetric pattern formed of a single layer of the first colloidal particles.

6. The method for producing a colloidal crystal according to claim 5, further comprising
a second layer formation step of bringing a dispersion of second colloidal particles having a charge opposite to that of the first colloidal particles into contact with the single layer of the first colloidal particles to electrostatically adsorb the second colloidal particles onto the single layer of the first colloidal particles after the immobilization step is performed.

7. The method for producing a colloidal crystal according to claim 6, further comprising
a third layer formation step of bringing a dispersion of third colloidal particles having a charge opposite to that of the second colloidal particles into contact with a single layer of the second colloidal particles to electrostatically adsorb the third colloidal particles onto the single layer of the second colloidal particles after the second layer formation step is performed.

8. The method for producing a colloidal crystal according to claim 7, wherein the second layer formation step and the third layer formation step are alternately repeated.

9. The method for producing a colloidal crystal according to claim 5, wherein
a surface of the substrate or surfaces of the colloidal particles in the dispersions of the colloidal particles is/are chemically modified with a modifying group capable of imparting a charge, and
the immobilization step is performed by eliminating ions in the dispersions of the colloidal particles, which exist between the substrate and the opposed plate.

10. The method for producing a colloidal crystal according to claim 6, wherein
a surface of the substrate or surfaces of the colloidal particles in the dispersions of the colloidal particles is/are chemically modified with a modifying group capable of imparting a charge, and
the immobilization step is performed by eliminating ions in the dispersions of the colloidal particles, which exist between the substrate and the opposed plate.

11. The method for producing a colloidal crystal according to claim 7, wherein
a surface of the substrate or surfaces of the colloidal particles in the dispersions of the colloidal particles is/are chemically modified with a modifying group capable of imparting a charge, and
the immobilization step is performed by eliminating ions in the dispersions of the colloidal particles, which exist between the substrate and the opposed plate.

12. The method for producing a colloidal crystal according to claim 8, wherein
a surface of the substrate or surfaces of the colloidal particles in the dispersions of the colloidal particles is/are chemically modified with a modifying group capable of imparting a charge, and
the immobilization step is performed by eliminating ions in the dispersions of the colloidal particles, which exist between the substrate and the opposed plate.
